(19) United States
(12) Patent Application Publication
(10) Pub. No.: US 2005/0032365 A1
(43) Pub. Date: Feb. 10, 2005

(54) Atomic layer deposition of metal during the formation of a semiconductor device

(76) Inventor: Eugene P. Marsh, Boise, ID (US)

Correspondence Address: Kevin D. Martin, 8000 S. Federal Way, MS 01-525, Boise, ID, 83707-0006, US

(21) Appl. No.: 10/637,362

(22) Filed: Aug. 8, 2003

(51) Int. Cl. H01L 21/44

(52) U.S. Cl. 438/681

(57) ABSTRACT

A method for forming a metal layer over a semiconductor wafer substrate assembly using atomic layer deposition (ALD) comprises exposing the surface of the wafer substrate assembly to a precursor gas to form a precursor layer over the surface of the wafer substrate assembly. Next, the precursor layer is exposed to a reducing gas which converts the precursor layer to a metal layer. One particular embodiment proposes the use of cyclopentadienylcobalt dicarbonyl as the precursor gas and hydrogen as the reducing gas to form a cobalt layer over the wafer surface.

### FIELD OF THE INVENTION

This invention relates to the field of semiconductor manufacture and, more particularly, to a method for forming a pure metal layer using atomic layer deposition.

### BACKGROUND OF THE INVENTION

During the manufacture of semiconductor devices such as dynamic random access memories, static random access memories, logic devices, and microprocessors, several structures are commonly formed. For example, conductive interconnects such as word lines, and conductive plugs such as digit line contact plugs, are commonly used.

A common engineering goal during the design of semiconductor devices is to manufacture as many features in a given area as possible. An obvious method to aid in accomplishing this goal is to make feature sizes smaller. One problem resulting from smaller feature sizes is that decreasing the width of a conductive line or conductive plug decreases the cross-sectional area of the line or plug, which in turn increases the resistance of the feature. Features which were originally manufactured from only conductively-doped polysilicon, which has a relatively high resistance, required the formation of a lower resistance material to decrease the overall resistance of the feature, for example an overlying layer of silicide such as tungsten silicide.

As device feature sizes further decrease it becomes desirable to form the entire feature from a highly-conductive material such as a metal, for example cobalt. Deposition techniques for metals include various methods. During sputtering, a target manufactured from the deposition material is bombarded with ions to erode the material from the target and redeposit it onto a semiconductor wafer substrate assembly. During chemical vapor deposition (CVD), gasses are mixed within a chamber and chemically combine, then deposit onto the wafer substrate surface. Both of these processes result in the continued increase in thickness during the process. As long as the process continues the thickness of the layer increases. Both CVD and sputtering can be used to deposit oxides as well as metals.

Thickness uniformity of a layer formed by either CVD or sputtering depends on a variety of factors. For CVD, the gasses to be combined must be dispersed uniformly above the surface receiving the layer to be deposited, otherwise the layer may form thicker in the areas of higher gas concentrations. The uniformity of a sputtered layer is highly dependent on the topography of the surface receiving the deposited layer.

Another method of forming a layer is atomic layer deposition (ALD). With ALD, gasses are mixed within a chamber and bond with free binding sites on the surface of the wafer substrate assembly to form a layer which is a single atom or molecule thick. Once all the binding locations are full, chemical deposition stops regardless of how much vapor remains in the chamber. ALD has the advantage over CVD and sputtering in that it forms a highly conformal layer over severe topography. However, ALD is typically used with dielectrics such as oxides and with nitrides, for example metal oxides and metal nitrides, while the deposition of pure metals with ALD has proven to be difficult.

A method which allows atomic layer deposition of a metal such as cobalt would be desirable.

### SUMMARY OF THE INVENTION

An embodiment of the present invention provides a new method which, among other advantages, forms a layer of metal such as cobalt using an atomic layer deposition process. In accordance with one embodiment of the invention a semiconductor wafer assembly is placed into a deposition chamber. A cobalt precursor, for example cyclopentadienylcobalt dicarbonyl, is flowed into the chamber using a carrier gas at specified flow rates and pressures, for a specified duration, to result in an atomic layer of a compound comprising cobalt. Next, the flow of the cobalt precursor is halted and a reducer such as hydrogen gas is flowed into the chamber to reduce the compound comprising cobalt, which results in a layer of cobalt metal over the surface of the wafer substrate assembly.

Advantages will become apparent to those skilled in the art from the following detailed description read in conjunction with the appended claims and the drawings attached hereto.

### BRIEF DESCRIPTION OF THE DRAWINGS

FIGS. 1-5 are cross sections of an in-process semiconductor device formed according to a first embodiment of the invention which results in a conductive plug;

FIGS. 6-7 are cross sections of an in-process semiconductor device formed according to a second embodiment of the invention which results in capacitor bottom plates;

FIG. 8 is an isometric depiction of a use of the invention in an electronic device; and

FIG. 9 is a block diagram of an exemplary use of the invention to form part of a memory array in a dynamic random access memory.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE PREFERRED EMBODIMENT

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

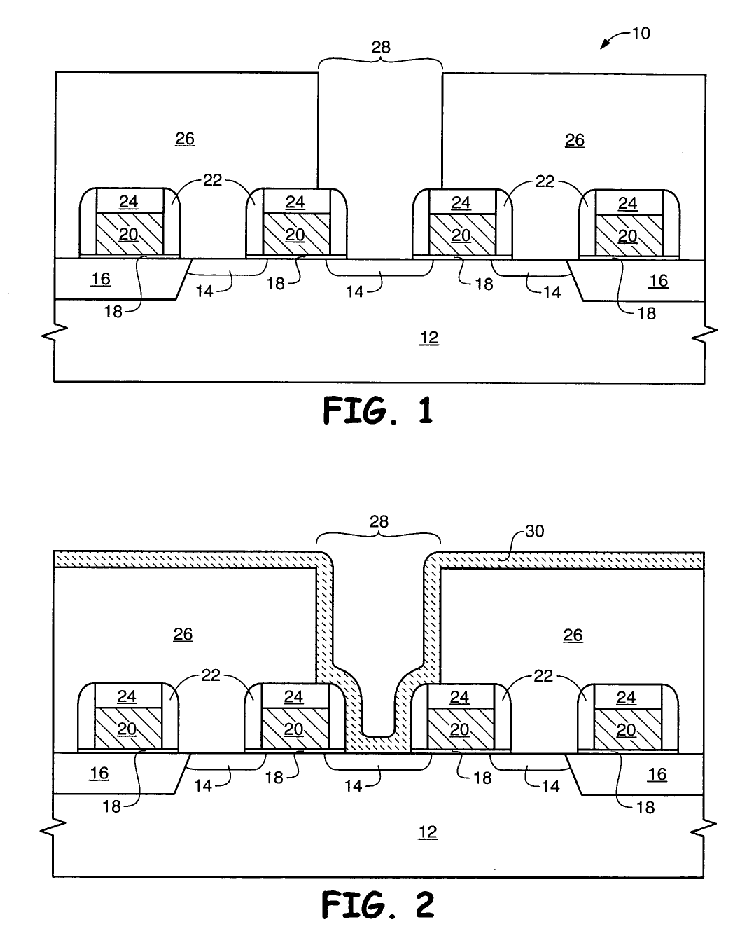

A process for forming a pure metal layer such as cobalt using atomic layer deposition (ALD) can be performed on a semiconductor wafer substrate assembly such as that depicted in FIG. 1. It should be noted that the term “pure metal layer” as used herein denotes that the layer consists essentially of atomic or molecular metal rather than a metal oxide, metal nitride, metal alloy, or some other molecule having more than one predominant element. However, there may be some contamination by another metal or nonmetal within the pure metal layer.

FIG. 1 depicts a semiconductor wafer substrate assembly 10 comprising a semiconductor wafer 12 having conductively-doped regions 14 therein, shallow trench isolation (STI) 16, gate oxide 18, transistor word line (control gate) 20 often comprising polysilicon and tungsten silicide, dielectric spacers 22 and transistor capping layer 24, and a silicon dioxide dielectric layer 26 often formed using a tetraethyl orthosilicate process or from borophosphosilicate glass (BPSG). An opening 28 in dielectric layer 26 exposes one of the doped regions 14 to which, in this exemplary embodiment, a digit line contact plug will be manufactured. The FIG. 1 structure can be manufactured by one of ordinary skill in the art from the information herein.

After forming the FIG. 1 structure, it is placed into a deposition chamber (or remains in the chamber from a previous process) such as an Applied Materials Centura or a TEL Unity, and a metal precursor is flowed into the chamber. To form a cobalt metal layer, cyclopentadienylcobalt dicarbonyl (C₅H₅CO(CO)₂) is flowed into the chamber using a carrier gas such as helium or argon at a flow rate of between about 0.0 standard cubic centimeters per minute (sccm) and about 1,000 sccm, and more preferably at a flow rate of between about 10 sccm and about 100 sccm for a duration of between about 0.1 seconds and about 10 seconds. As is known by one of ordinary skill in the art, at a flow rate of 0.0 sccm some gas is injected into the chamber due to the lower chamber pressure with low pressure processes.

During the flow of the precursor gas into the chamber, the temperature of the wafer substrate assembly is maintained to between about 220° C. and about 320° C., and more preferably to between about 240° C. and about 280° C., and the chamber pressure is maintained at between about 0.01 millitorr (mT) and about 1 Torr (T), and more preferably between about 0.1 mT and about 100 mT.

Referring to FIG. 2, cyclopentadienylcobalt dicarbonyl chemically combines with the exposed surfaces of the wafer assembly to form a blanket conformal precursor layer 30 over the surface of the semiconductor wafer substrate assembly. While the bonding mechanism has not been fully studied, it is believed the cyclopentadienylcobalt dicarbonyl loses a ligand, either a carbonyl or the cyclopentadienyl group, to bind to the exposed surface of the wafer substrate assembly. Once all binding sites are filled, continued formation of the precursor layer ceases so that continuing the flow of cyclopentadienylcobalt dicarbonyl adds no further increase to the thickness of layer 30, which forms as a layer a single molecule thick (i.e. a monolayer).

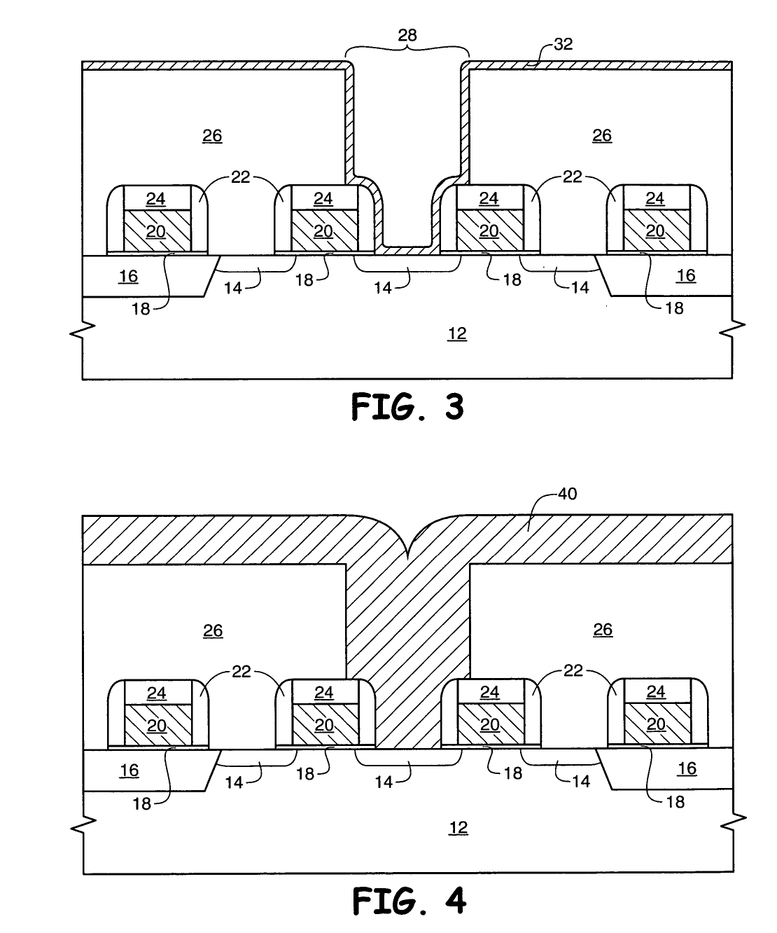

After exposing the surfaces to cyclopentadienylcobalt dicarbonyl to form the initial layer 30, a reducer such as hydrogen (H₂) is flowed into the chamber at a flow rate of between about 50 sccm and about 1,000 sccm for a duration of between about 0.1 seconds and about 10 seconds. The hydrogen reduces the layer over the surface of the wafer substrate assembly to leave cobalt metal 32 covering the surface as depicted in FIG. 3. The remaining products of the reaction are then pumped out of the chamber. The reduction of layer 30 to cobalt metal 32 has not been fully studied, and the byproducts produced are not known. However, upon reduction of initial layer 30 to metal, the process produces less than a complete blanket layer of metal and the process needs to be repeated several times to ensure complete coverage of the metal across the exposed assembly surface. It is estimated that a single cycle comprising precursor formation then reduction of the precursor results in a metal layer which covers about 33% of the exposed surface with metal, and forms a cobalt layer about 0.7 angstroms (Π) thick

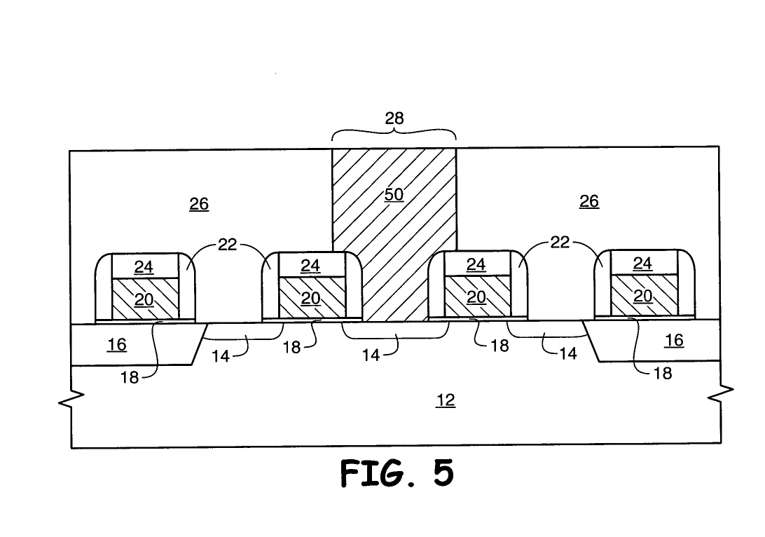

Once layer 30 has been reduced to cobalt metal 32, the cyclopentadienylcobalt dicarbonyl can again be flowed, followed by the flow of H₂ to form a second cobalt layer directly on the first cobalt layer. This process is repeatable for any number of iterations of the cyclopentadienylcobalt dicarbonyl flow followed by the H₂ flow, and thus a cobalt feature having a desired thickness can be formed by repeating these two parts of the process. FIG. 4 depicts the results of a process which repeats the two parts of the process a sufficient number of times to fill the opening 28 in the dielectric layer 12 with metal 40. After forming the FIG. 4 structure, the surface of the assembly can be planarized, for example using mechanical planarization or chemical mechanical planarization, to result in the structure of FIG. 5 having a conductive cobalt plug 50. Wafer processing then continues according to means known in the art.

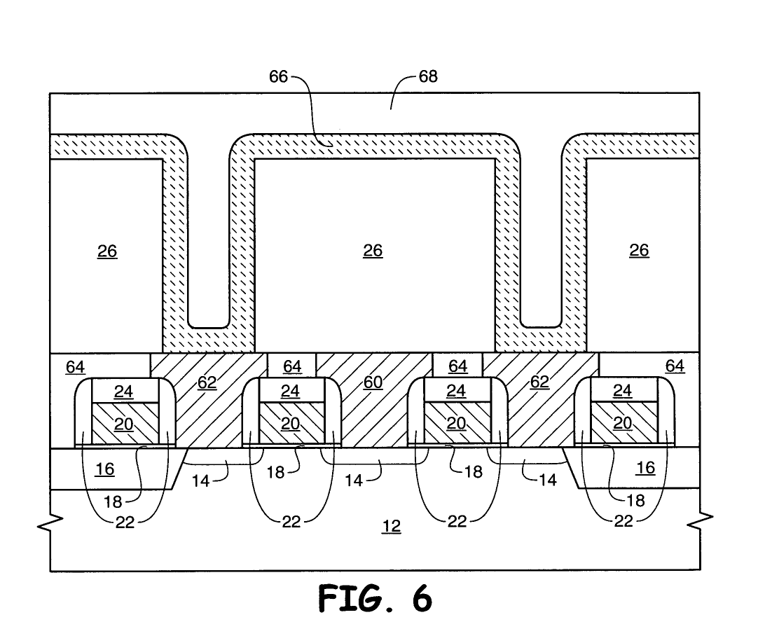

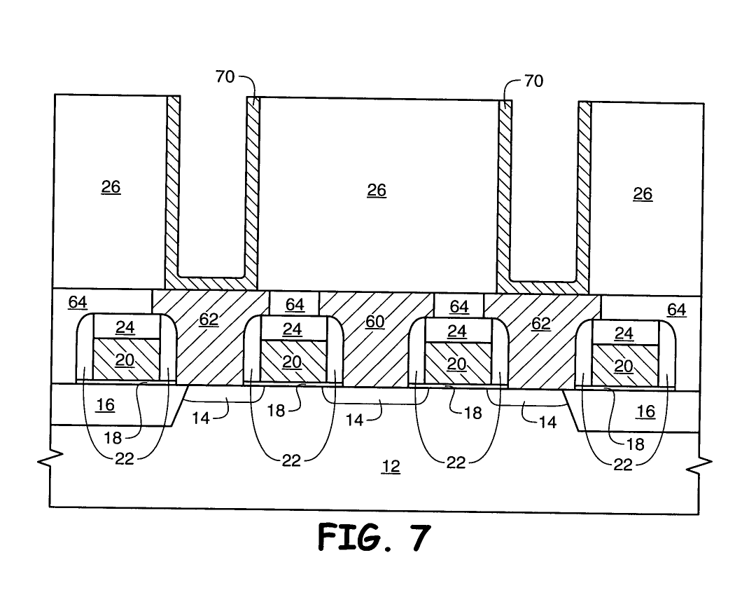

FIGS. 6 and 7 depict a use of the invention to form a capacitor bottom plate during the formation of a semiconductor device such as a dynamic random access memory device. FIG. 6 depicts a semiconductor wafer substrate assembly comprising a semiconductor wafer 12 having conductively-doped regions 14 therein, shallow trench isolation (STI) 16, gate oxide 18, transistor word line (control gate) 20 often comprising polysilicon and tungsten silicide, dielectric spacers 22 and transistor capping layer 24, and a silicon dioxide dielectric layer 26 often formed using a tetraethyl orthosilicate process or from borophosphosilicate glass (BPSG). FIG. 6 further depicts conductive plugs 60, 62 separated by a dielectric layer 64. A conformal pure metal layer 66, which provides a capacitor bottom plate layer, is formed to physically contact dielectric 26 and plugs 62. An adhesion layer (not depicted) may also be formed on the plugs 62 and/or the dielectric 26 prior to formation of the metal layer 66. The process of exposing the substrate assembly to cyclopentadienylcobalt dicarbonyl then reducing the cyclopentadienylcobalt dicarbonyl-formed layer to pure metal by exposure to hydrogen is performed a sufficient number of times to form a pure metal layer adequately thick to provide capacitor bottom plate layer 66. With current technology, this layer is between about 100Π and about 200Π thick. Next, a blanket protective layer 68, for example photoresist, is formed within the recesses formed by the bottom plate.

After forming the protective layer 68, the structure of FIG. 6 is planarized, for example using mechanical planarization or chemical mechanical planarization to remove layer 66 from the horizontal upper surface of layer 26 and to form discrete capacitor bottom plates. The protective layer 68 prevents contaminants from entering the recesses formed by the bottom plates during this planarization, which can be difficult to remove. Next, the protective layer 68 is removed from within the recesses formed by the bottom plate to result in the structure of FIG. 7 comprising capacitor bottom plates 70 electrically isolated from each other and each electrically coupled to polysilicon pads 62. Wafer processing continues according to means known in the art, for example to form capacitor dielectric, capacitor top plates, and digit line contacts.

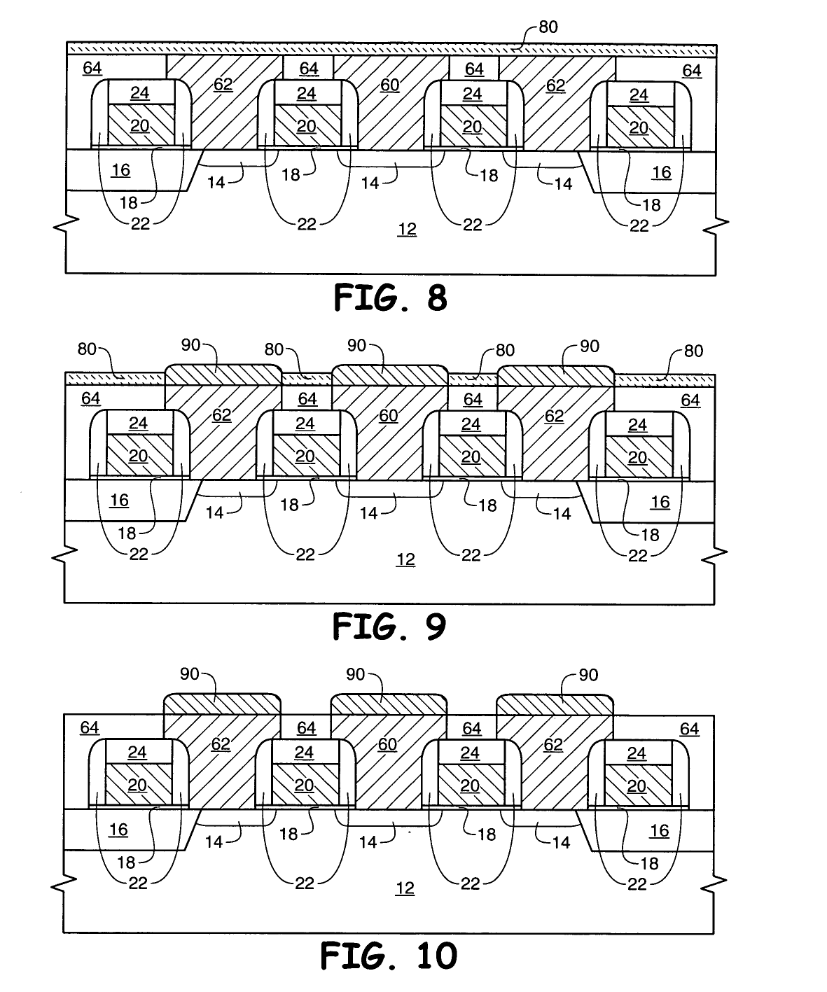

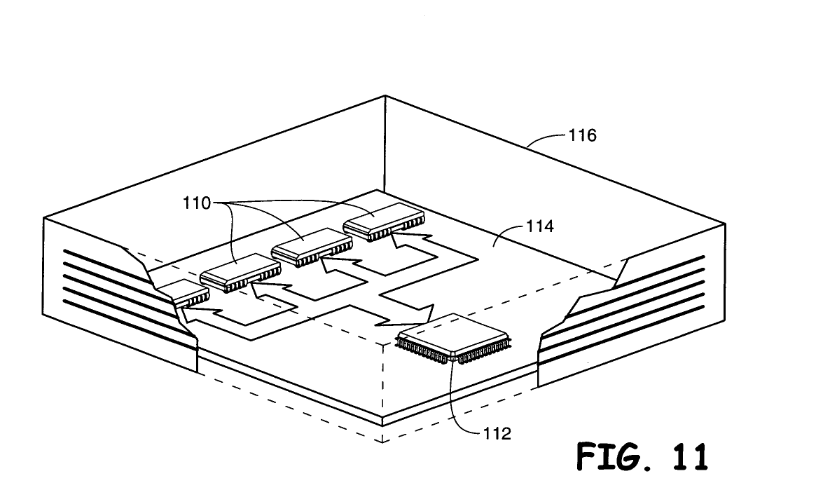

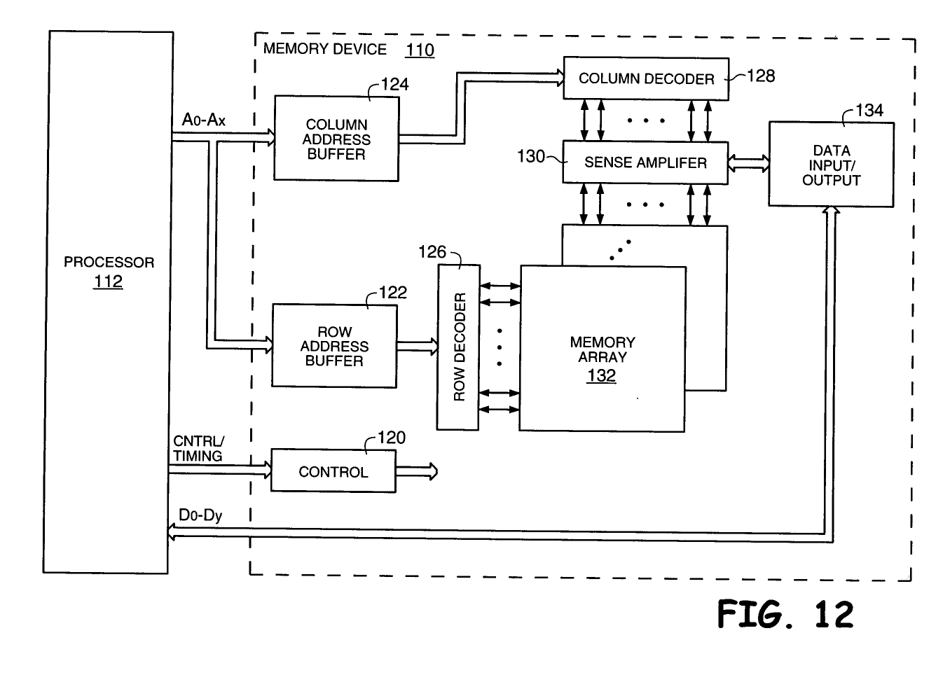

An embodiment of the present process can also be used to form a metal silicide layer such as a cobalt silicide (CoSiₓ) layer. In this embodiment, the structure such as that depicted in FIG. 8 is formed, or a similar structure where a metal silicide layer over a silicon layer is desirable. FIG. 8 depicts a semiconductor wafer substrate assembly comprising a semiconductor wafer 12 having conductively-doped regions 14 therein, shallow trench isolation (STI) 16, gate oxide 18, transistor word line (control gate) 20 often comprising polysilicon and tungsten silicide, dielectric spacers 22 and transistor capping layer 24. FIG. 8 further depicts conductive plugs 60, 62 separated by a dielectric layer 64. Metal layer 80 is formed by exposing the substrate assembly to cyclopentadienylcobalt dicarbonyl then reducing the cyclopentadienylcobalt dicarbonyl-formed layer to pure metal by exposure to hydrogen according to the method previously described. A sufficient number of cycles are completed to form a pure metal layer between about 50Π and about 75Π thick. As this layer forms at a rate of about 0.7 Π each cycle, the process is performed between about 70 times and about 110 times. Next, the structure is annealed, for example by exposing the wafer assembly to a temperature of between about 350° C. and about 600° C. in forming gas or an inert ambient, for example in a nitrogen ambient, for a duration of between about 30 seconds and about 30 minutes. This anneal results in the FIG. 9 structure and causes the cobalt metal 80 and the polysilicon of plugs 62 to react, resulting in the formation of cobalt silicide 90 on the plugs 62, while the cobalt metal 80 over dielectric 64 does not react.

Next, the unreacted cobalt metal is removed using an etch comprising hydrochloric acid which removes the cobalt metal selective to the cobalt silicide and results in the structure of FIG. 10. Wafer processing continues, for example to form digit line contacts to the silicide 90 on one or more of plugs 62, or capacitor bottom plates to contact the silicide 90 on one or more of plugs 62.

Another use of the invention comprises forming a cobalt metal layer as a seed layer, for example during electroplating or electroless plating of a cobalt layer. After forming a cobalt metal seed layer according to the process described above, the wafer may be immersed in a solution of about 0.082 molar (M) CoSO₄·7H₂O, 0.502 M H₃BO₃, and about 0.169 M NaH₂PO₂·2H₂O at about 90° C. and a pH of about 8.8 to about 9.0 until a desired cobalt thickness is obtained. The thickness of the final cobalt layer is dependent upon its use, and various uses and thicknesses will be evident to one of ordinary skill in the art from the description herein.

As depicted in FIG. 11, a semiconductor device 110 formed in accordance with the invention may be attached along with other devices such as a microprocessor 112 to a printed circuit board 114, for example to a computer motherboard or as a part of a memory module used in a personal computer, a minicomputer, or a mainframe 116. FIG. 11 may also represent use of device 110 in other electronic devices comprising a housing 116, for example devices comprising a microprocessor 112, related to telecommunications, the automobile industry, semiconductor test and manufacturing equipment, consumer electronics, or virtually any piece of consumer or industrial electronic equipment.

The process and structure described herein can be used to manufacture a number of different structures. FIG. 12, for example, is a simplified block diagram of a memory device such as a dynamic random access memory having a memory array with container capacitors, transistors with control gates, digit lines, and other metal structures, many of which may be formed using an embodiment of the present invention. The general operation of such a device is known to one skilled in the art. FIG. 12 depicts a processor 112 coupled to a memory device 110, and further depicts the following basic sections of a memory integrated circuit: control circuitry 120; row 122 and column 124 address buffers; row 126 and column 128 decoders; sense amplifiers 130; memory array 132; and data input/output 134.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

1. A method used to form a semiconductor device, comprising:
placing a semiconductor wafer substrate assembly having a surface into a deposition chamber;
introducing cyclopentadienylcobalt dicarbonyl into the chamber to deposit a cobalt metal precursor layer by atomic layer deposition over the surface of the semiconductor wafer substrate assembly; and
introducing hydrogen into the deposition chamber to convert the precursor layer such that a pure metal layer of cobalt remains over the surface of the semiconductor wafer substrate assembly.

2. The method of claim 1 wherein the introduction of hydrogen into the deposition chamber results in a pure metal layer of cobalt which covers about 33% of the semiconductor wafer substrate assembly surface.

3. The method of claim 1 further comprising performing the introduction of cyclopentadienylcobalt dicarbonyl then the introduction of hydrogen a plurality of times to form a blanket pure metal layer of cobalt.

4. The method of claim 1 further comprising:
forming a silicon plug as part of the semiconductor wafer substrate assembly;
subsequent to forming the silicon plug, placing the semiconductor wafer substrate assembly into the deposition chamber;
depositing the cobalt metal precursor layer on the silicon plug;
converting the precursor layer on the silicon plug to the pure metal layer of cobalt; and
annealing the pure metal layer of cobalt on the silicon plug to react the pure metal layer of cobalt with the silicon plug to convert the pure metal layer of cobalt on the plug to cobalt suicide.

5. The method of claim 1 further comprising:
flowing cyclopentadienylcobalt dicarbonyl and a carrier gas Into the chamber at a flow rate of between about 0.0 standard cubic centimeters per minute (sccm) and about 1,000 sccm for a duration of between about 0.1 seconds and about 10 seconds during the introduction of cyclopentadienylcobalt dicarbonyl into the deposition chamber;
maintaining the wafer substrate assembly at a temperature of between about 220° C. and about 320° C. during the introduction of cyclopentadienylcobalt dicarbonyl into the deposition chamber.

6. A method used to form a semiconductor device comprising:
placing a semiconductor wafer substrate assembly surface comprising an dielectric layer and a silicon layer into a deposition chamber;
exposing the dielectric layer and the silicon layer to cyclopentadienylcobalt dicarbonyl to form a cobalt precursor layer on the dielectric layer and on the silicon layer;
exposing the cobalt precursor layer to a reducer which converts the cobalt precursor layer to a pure metal layer of cobalt;
annealing the pure metal layer of cobalt to react the pure metal layer of cobalt with the silicon layer to form cobalt suicide while the pure metal layer of cobalt which contacts the dielectric layer remains unreacted; and
removing the pure metal layer of cobalt which remains after annealing the pure metal layer of cobalt.

7. The method of claim 6 further comprising heating the pure metal layer of cobalt, the silicon layer, and the dielectric layer to a temperature of between about 350° C. and about 600° C. during the annealing.

8. The method of claim 6 further comprising forming a digit line contact which contacts the silicide.

9. The method of claim 6 further comprising forming a capacitor bottom plate which contacts the suicide.

10. A method to form an electronic device comprising;
placing a substrate assembly into a deposition chamber;
introducing cyclopentadienylcobalt dicarbonyl into the chamber to deposit a cobalt metal precursor layer by atomic layer deposition over the surface of the substrate assembly;
introducing hydrogen into the deposition chamber to convert the precursor layer such that a pure metal layer of cobalt having a first thickness remains over the surface of the substrate assembly;
removing the substrate assembly having the cobalt metal layer formed thereover from the deposition chamber;
immersing the substrate assembly having the cobalt metal layer into a plating solution which uses the cobalt metal layer as a seed layer; and
removing the substrate assembly from the plating solution, wherein subsequent to removing the substrate assembly from the plating solution the cobalt metal layer has a second thickness which is thicker than the first thickness.

11. The method of claim 10 wherein the immersing of the substrate further comprises immersing the substrate assembly having the pure metal layer of cobalt into a plating solution comprising about 0.082 molar CoSO₄·7H₂O, 0.502 molar H₃BO₃, and about 0.169 molar NaH₂PO₂·2H₂O.

12. The method of claim 11 further comprising heating the plating solution to about 90° C. prior to immersing the substrate assembly into the plating solution.

13. The method of claim 12 further comprising formulating the plating solution to a pH of between about 8.8 to about 9.0.
